(19) United States
(12) Patent Application Publication
(10) Pub. No.: US 2026/0314093 A1
(43) Pub. Date: Oct. 8, 2026

(54) IMAGE SENSOR

(71) Applicant: Samsung Electronics Co., Ltd., Suwon-si (KR)

(72) Inventors: Sungbong PARK, Suwon-si (KR); Chang-Ki BAEK, Suwon-si (KR); Jaekyu LEE, Suwon-si (KR); Ki Yeong KIM, Suwon-si (KR)

(73) Assignees: Samsung Electronics Co., Ltd., Suwon-si (KR); POSTECH RESEARCH AND BUSINESS DEVELOPMENT FOUNDATION, Pohang-si (KR)

(21) Appl. No.: 19/458,173

(22) Filed: Jan. 23, 2026

(30) Foreign Application Priority Data
Apr. 8, 2025 (KR) 10-2025-0045666

(51) Int. Cl. H10F 39/00; H10F 39/18

(52) U.S. Cl. CPC H10F 39/80377; H10F 39/182; H10F 39/809

(57) ABSTRACT

An image sensor according to an embodiment may include a substrate comprising a photoelectric conversion area; and a source follower transistor on one side of the substrate, wherein the source follower transistor may include a source area, a channel area, and a drain area on the substrate. The source area may be doped a first conductivity type. The channel area and the drain area may be doped a second conductivity type. The second conductivity type may be different from the first conductivity type.

### CROSS-REFERENCE TO RELATED APPLICATION

This application claims priority to and the benefit of Korean Patent Application No. 10-2025-0045666 filed with the Korean Intellectual Property Office on Apr. 8, 2025, the entire contents of which are incorporated herein by reference.

### BACKGROUND

### Field

The present disclosure relates to an image sensor.

### Description of the Related Art

An image sensor is a semiconductor device that converts an optical image into an electrical signal. The image sensor may be classified into a charge coupled device CCD type and a complementary metal oxide semiconductor (CMOS) type. The CMOS type image sensor is abbreviated as a CIS(CMOS image sensor). The CIS includes a plurality of pixels arranged in two dimensions. Each of the pixels includes a photodiode PD. The photodiode serves to convert incident light into an electrical signal.

### SUMMARY

The present disclosure relates to an image sensor with improved noise.

An image sensor according to an embodiment may include a substrate comprising a photoelectric conversion area; and a source follower transistor on one side of the substrate. The source follower transistor may include a source area, a channel area, and a drain area on the substrate. The source area may be doped a first conductivity type. The channel area and the drain area may be doped a second conductivity type. The second conductivity type may be different from the first conductivity type.

According to an embodiment, an image sensor may include:
a first substrate comprising a photoelectric conversion area, wherein a first surface of the first substrate is opposite a second surface of the first substrate;
a transfer transistor and a floating diffusion region on the first surface of the first substrate;
a second substrate, wherein a first surface of the second substrate is opposite and a second surface of the second substrate; and
a plurality of transistors on the first surface of the second substrate and connected to the transfer transistor,
wherein the plurality of transistors on the second substrate each may comprise a reset transistor configured to initialize the floating diffusion region, a source follower transistor having a gate connected to the floating diffusion region, and a selection transistor connected to one end of the source follower transistor, and
wherein the source follower transistor may include a source area, a channel area, and a drain area on the second substrate,
wherein the source follower transistor further may include a gate electrode overlapping the channel area,
the source area may be doped a first conductivity type,
the channel area and the drain area may be doped a second conductivity type, and
the second conductivity type may be different from the first conductivity type.

According to an embodiment, an image sensor may include a substrate including a photoelectric conversion area, a transfer transistor connected to the photoelectric conversion area, a floating diffusion region connected to the transfer transistor, a source follower transistor having a gate connected to the floating diffusion region, a reset transistor configured to initialize the floating diffusion region, and a selection transistor connected to one end of the source follower transistor. The source follower transistor may include a source area, a channel area, and a drain area on the substrate. The source area may be doped a first conductivity type. The channel area and the drain area may be doped a second conductivity type. The second conductivity type may be different from the first conductivity type.

According to example embodiments, the present disclosure provides an image sensor with improved noise.

### BRIEF DESCRIPTION OF THE DRAWINGS

FIG. 1 is a block diagram of an image sensor according to an embodiment.

FIG. 2 is a circuit diagram of one pixel included in image sensors according to embodiments of the present disclosure.

FIG. 3 is a plan view illustrating an image sensor according to embodiments of the present disclosure.

FIG. 4 is a portion of a cross-section of one pixel PX of the image sensor according to the present embodiment.

FIG. 5 is an enlarged view of the source follower transistor of FIG. 4.

FIG. 6 is a simplified diagram of the structure of a typical source follower transistor.

FIG. 7 is a simplified diagram of the structure of a source follower transistor having a buried channel.

FIG. 8 is a simplified diagram of the structure of a tunneling source follower transistor including a tunneling mechanism according to the present embodiment.

FIG. 9 is an output voltage under a constant drain voltage (V_{D}=3.0V) and a constant drain current (I_{D}=100 nA) condition with respect to transistors of FIGS. 6 to 8.

FIG. 10 is a voltage gain under a constant drain voltage (V_{D}=3.0V) and a constant drain current (I_{D}=100 nA) condition with respect to transistors of FIGS. 6 to 8.

FIG. 11 is an output conductance g_{ds} under a constant drain voltage V_{D}=3.0V and a constant drain current (I_{D}=100 nA) condition with respect to transistors of FIGS. 6 to 8.

FIG. 12 is a constant drain voltage (V_{D}=3.0V) and a body effect trans conductance gmb under a constant drain current (I_{D}=100 nA) condition for transistors of FIGS. 6 to 8.

FIG. 13 is a trans conductance gm under a constant drain voltage (V_{D}=3.0V) and a constant drain current (I_{D}=100 nA) condition.

FIG. 14 is the sum of the output conductance and the body effect trans conductance ((gds+gmb)/gm) versus the trans conductance for the transistors of FIG. 6 to 8.

FIG. 15 is the input-referred voltage noise spectral density SV for the transistors of FIGS. 6 to 8 under conditions of a constant drain voltage (V_{D}=3.0V) and a constant drain current (I_{D}=100 nA).

FIG. 16 is the input-referred current noise spectral density SI for the transistors of FIG. 6 to 8 under conditions of a constant drain voltage (V_{D}=3.0V) and a constant drain current (I_{D}=100 nA).

FIG. 17 is the same cross-section as FIG. 4 for another embodiment.

FIG. 18 is the same cross-section as FIG. 17 for another embodiment.

### DETAILED DESCRIPTION

Hereinafter, various embodiments of the present disclosure will be described in detail with reference to the accompanying drawings so that those skilled in the art may easily implement the present disclosure. The present disclosure may be implemented in several different forms and is not limited to the embodiments described herein.

In order to clearly explain the present disclosure, parts that do not have a relationship with the explanation are omitted, and identical or similar components are assigned the same reference numerals throughout the specification.

In addition, the size and thickness of each component shown in the drawing are arbitrarily shown for better understanding and ease of description, so the present disclosure is not necessarily limited to what is shown. In the drawings, the thickness of layers, films, panels, areas, etc., are exaggerated for clarity. And, in the drawings, for the convenience of explanation, the thickness of some layers and areas is exaggerated.

Additionally, when a part of a layer, film, area, substrate, etc. is referred to be “above” or “on” another part, this may include not only cases where it is “directly on” another part, but also cases where there are intervening elements in between. In contrast, when an element is referred to as being “directly on” another element, there are no intervening elements present. In addition, being “above” or “on” a reference part means being positioned above or below the reference part, and does not necessarily mean being positioned “above” or “on” it in the opposite direction of gravity.

In addition, throughout the specification, when a part is referred to “include” a certain component, this means that it may further include other components rather than excluding other components, unless specifically stated to the contrary.

In addition, throughout the specification, when it comes to “on a plane,” it means when the target part is viewed from above, and when it comes to “cross-section,” it means when the cross-section of the target part is vertically cut from the side.

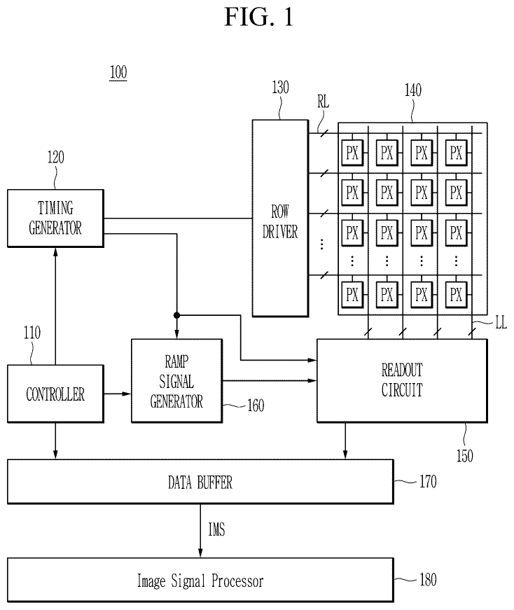

FIG. 1 is a block diagram of an image sensor according to an embodiment.

Referring to FIG. 1, an image sensor 100 according to an embodiment may include a controller 110, a timing generator 120, a row driver 130, a pixel array 140, a readout circuit 150, a ramp signal generator 160, a data buffer 170, and an image signal processor 180. In an embodiment, the image signal processor 180 may be positioned outside of the image sensor 100.

The image sensor 100 may generate an image signal IMS by converting light received from the outside into an electrical signal. The image signal IMS may be provided to the image signal processor 180.

The image sensor 100 may be mounted on an electronic device having an image or light sensing function. For example, the image sensor 100 may be mounted in electronic devices such as cameras, smartphones, wearable devices, Internet of Things (IoT) devices, home appliances, personal computers, personal digital assistants (PDAs), portable multimedia players (PMPs), navigations, drones, and advanced drivers assistance systems (ADAS). Also, the image sensor 100 may be mounted in an electronic device provided as a part of a vehicle, furniture, manufacturing facility, door, or various measuring devices.

The controller 110 may generally control each of the components 120, 130, 150, 160, 170 included in the image sensor 100. The controller 110 may control operation timing of each of the components 120, 130, 140, 150, 160, 170 using control signals. In an embodiment, the controller 110 may receive a mode signal indicating an image mode from the application processor, and may generally control the image sensor 100 based on the received mode signal. For example, the application processor may determine the image mode of the image sensor 100 according to various scenarios such as the illuminance of the imaging environment, the user's resolution setting, and the sensed or learned state, and provide the determined result to the controller 110 as a mode signal. The controller 110 may control a plurality of pixels of the pixel array 140 to output a pixel signal according to an image mode. The pixel array 140 may output a pixel signal for each of the plurality of pixels or a pixel signal for some of the plurality of pixels. The readout circuit 150 may sample and process pixel signals received from the pixel array 140. The timing generator 120 may provide a control signal for controlling the timing of the row driver 130, the readout circuit 150, and the ramp signal generator 160. The timing generator 120 may control the timing of the row driver 130, the readout circuit 150, and the ramp signal generator 160. The timing generator 120 may provide a control signal for controlling the timing of the row driver 130, the readout circuit 150, and the ramp signal generator 160.

The pixel array 140 may include a plurality of pixels PX, a plurality of row lines RL and a plurality of column lines LL respectively connected to the plurality of pixels PX. In an embodiment, each pixel PX may include at least one or more photovoltaic devices. The photovoltaic device may detect incident light and convert the incident light into an electrical signal according to the amount of light, that is, a plurality of analog pixel signals. The photovoltaic device may be a photodiode, a pinned diode, or the like. In addition, the photovoltaic device may be a single-photon avalanche diode SPAD applied to a 3D sensor pixel. The level of the analog pixel signal output from the photovoltaic device may be proportional to the amount of charge output from the photovoltaic device. That is, the level of the analog pixel signal output from the photovoltaic device may be determined according to the amount of light received into the pixel array 140.

A plurality of row lines RL may extend in a first direction and may be connected to pixels PX disposed along the first direction. For example, a control signal output from the row driver 130 to the row line RL may be transmitted to the gates of the transistors of the plurality of pixels PX connected to the row line RL. The column line LL extends in a second direction crossing the first direction, and may be connected to pixels PX disposed along the second direction. A plurality of pixel signals output from the plurality of pixels PX may be transmitted to the readout circuit 150 through the plurality of column lines LL.

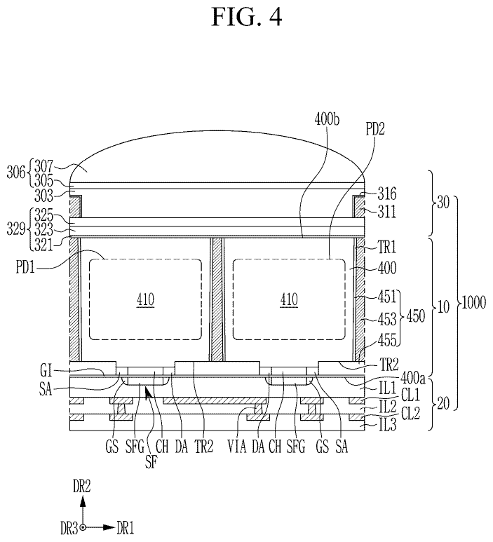

A color filter layer and a microlens layer may be positioned on the pixel array 140. The microlens layer may include a plurality of microlenses, and each of the plurality of microlenses may be positioned above at least one corresponding pixel PX. The color filter layer may include color filters such as red, green, and blue, and may further include a white filter. For one pixel PX, a color filter of one color may be positioned between the pixel PX and the corresponding microlens. A specific structure of the color filter layer and the microlens layer will be described later in FIG. 4.

The row driver 130 may generate a control signal for driving the pixel array 140 in response to the control signal of the timing generator 120 and provide a control signal to the plurality of pixels PX of the pixel array 140 through the plurality of row lines RL. In an embodiment, the row driver 130 may be controlled to detect incident light on a pixel PX by row line unit. The row line unit may include at least one row line RL. For example, as described later, the row driver 130 may provide the pixel array 140 with a transfer signal, a reset signal, and a selection signal.

In response to a control signal from the timing generator 120, the readout circuit 150 may convert a pixel signal (or an electrical signal) from pixels PX connected to a row line RL selected from among a plurality of pixels PX into a pixel value representing the amount of light. The readout circuit 150 may convert a pixel signal output through a corresponding column line LL into a pixel value. For example, the readout circuit 150 may convert the pixel signal into a pixel value by comparing the ramp signal with the pixel signal. The pixel value may be image data having a plurality of bits. Specifically, the readout circuit 150 may include a selector, a plurality of comparators, a plurality of counter circuits, and the like.

The ramp signal generator 160 may generate a reference signal and transmit the reference signal to the readout circuit 150.

The ramp signal generator 160 may include a current source, a resistor, and a capacitor. The ramp signal generator 160, by adjusting the current magnitude of a variable current source or the resistance value of a variable resistor to adjust the ramp voltage, which is the voltage across the ramp resistor, may generate a plurality of ramp signals that fall or rise with a slope determined by the current magnitude of the variable current source or the resistance value of the variable resistor.

The data buffer 170 may store pixel values of a plurality of pixels PX connected to the selected column line LL transmitted from the readout circuit 150 and may output the stored pixel values in response to the enable signal from the controller 110.

The image signal processor 180 may perform an image signal processing on the image signal received from the data buffer 170. For example, the image signal processor 180 may receive a plurality of image signals from the data buffer 170 and may synthesize the received image signals to generate a single image.

In an embodiment, a plurality of pixels may be grouped together in an M*N (M, N is an integer of 2 or more) array form to form one unit pixel group. The M*N array may be a form in which M pixels are arranged in the arrangement direction of the column line LL and N pixels are arranged in the arrangement direction of the row lines RL. For example, one unit pixel group may include a plurality of pixels arranged in the form of 2*2, and one unit pixel group may output one analog pixel signal. The following configuration is not limited to one pixel, but may also be applied to the unit pixel group.

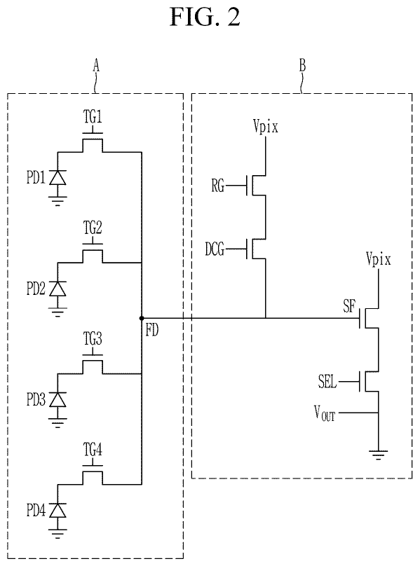

FIG. 2 is a circuit diagram of one pixel included in image sensors according to embodiments of the present disclosure.

Referring to FIG. 2, one pixel may include a plurality of photovoltaic devices PD1, PD2, PD3, PD4. Each of the photovoltaic devices PD1, PD2, PD3, PD4 (e.g., photodiodes) may perform photoelectric conversion. As illustrated in FIG. 2, a plurality of photovoltaic devices PD1, PD2, PD3, PD4 may be connected to one floating diffusion region FD. In FIG. 2, a configuration in which four photovoltaic devices are connected to one floating diffusion region FD is described, but this is only an example, and the number of photovoltaic devices connected to one floating diffusion region FD may vary according to embodiments.

Although the first photovoltaic device PD1 is mainly described below, the following description is equally applied to other photovoltaic devices PD2, PD3, PD4.

The first photovoltaic device PD1 may generate and accumulate electric charges according to the amount of light received. The first photovoltaic device PD1 may include an anode connected to the ground and a cathode connected to one end of the first transfer transistor TG1. A first transfer signal may be supplied to the gate of the first transfer transistor TG1, and one end of the first transfer transistor TG1 may be connected to the floating diffusion region FD. When the first transfer transistor TG1 is turned on by the first transfer signal, charges charged in the first photovoltaic device PD1 may be transferred to the floating diffusion region FD. The floating diffusion region FD may maintain the electric charge transferred from the photovoltaic device PD.

Each of a plurality of transfer transistors TG1, TG2, TG3, TG4 may include a gate electrode connected between one of a plurality of photovoltaic devices PD1, PD2, PD3, PD4 and a floating diffusion region FD to receive a plurality of transfer signals. The number of a plurality of transfer transistors TG1, TG2, TG3, TG4 may be equal to the number of a plurality of photovoltaic devices PD1, PD2, PD3, PD4.

A reset transistor RG may be connected between the power supply voltage Vpix and the floating diffusion region FD, and may include a gate electrode that receives the reset signal.

The reset transistor RG may periodically reset electric charges accumulated in the floating diffusion region FD. The drain electrode of the reset transistor RG may be connected to the source electrode of the dual conversion gain transistor DCG, and the source electrode may be connected to the power supply voltage Vpix. When the reset transistor RG is turned on, the power supply voltage Vpix connected to the source electrode of the reset transistor RG may be applied to the floating diffusion region FD. Therefore, when the reset transistor RG is turned on, the electric charges accumulated in the floating diffusion region FD may be discharged to reset the floating diffusion region FD.

The dual conversion gain transistor DCG may be positioned between the reset transistor RG and the floating diffusion region FD, and may include a gate electrode that receives the dual conversion signal. The dual conversion gain transistor DCG may reset the floating diffusion region FD together with the reset transistor RG.

The drain electrode of the dual conversion gain transistor DCG may be connected to the floating diffusion region FD, and the source electrode of the dual conversion gain transistor DCG may be connected to the drain electrode of the reset transistor RG. When the reset transistor RG and the dual conversion gain transistor DCG are turned on, the power supply voltage Vpix connected to the source electrode of the reset transistor RG may pass through the dual conversion gain transistor DCG and be applied to the floating diffusion region FD. Accordingly, the electric charges accumulated in the floating diffusion region FD may be discharged to reset the floating diffusion region FD.

The source follower transistor SF may output a pixel signal according to a voltage of the floating diffusion region FD. The gate of the source follower transistor SF may be connected to the floating diffusion region FD, the source electrode of the source follower transistor SF may be connected to one end of the selection transistor SEL, and the power supply voltage Vpix is supplied to the drain electrode of the source follower transistor SF. The source follower transistor SF may constitute a source follower circuit and may output a voltage of a level corresponding to the electric charge accumulated in the floating diffusion region FD as a pixel signal. As will be explained separately later, in the image sensor according to the present embodiment, the source follower transistor SF may have the channel and drain areas doped with the same conductivity type, and the source area may be doped with a different conductivity type. These source follower transistors may reduce noise without losing voltage gain by using band-to-band tunneling as the main electron transport mechanism. An example of the specific structure will be described later separately.

When the selection transistor SEL is turned on by the selection signal, a pixel signal from the source follower transistor SF may be transmitted to the readout circuit. A selection signal may be applied to the gate electrode of the selection transistor SEL, and the drain electrode of the selection transistor SL may be connected to an output wiring Vout outputting a plurality of pixel signals.

The operation of the image sensor will be described with reference to FIG. 2. First, while light is blocked, a power supply voltage Vpix is applied to the drain electrode of the reset transistor RG and the drain electrode of the source follower transistor SF, and the reset transistor RG and the dual conversion gain transistor DCG are turned on to discharge the electric charges remaining in the floating diffusion region FD. After that, when the reset transistor RG is turned off and light from the outside is incident on the photovoltaic devices PD1, PD2, PD3, PD4, an electron-hole pair is generated in each of the photovoltaic devices PD1, PD2, PD3, PD4. Holes move to the p-type impurity area of the photovoltaic devices PD1, PD2, PD3, PD4, and electrons move to the n-type impurity area and accumulate. When the transfer transistor(s) TG1, TG2, TG3, TG4 are turned on, charges such as electrons and holes are transferred to and accumulated in the floating diffusion region FD. The gate bias of the source follower transistor SF may change in proportion to the accumulated amount of electric charge, resulting in a change in the source potential of the source follower transistor SF. At this time, when the selection transistor SEL is turned on, a signal due to an electric charge may be read through the output line Vout.

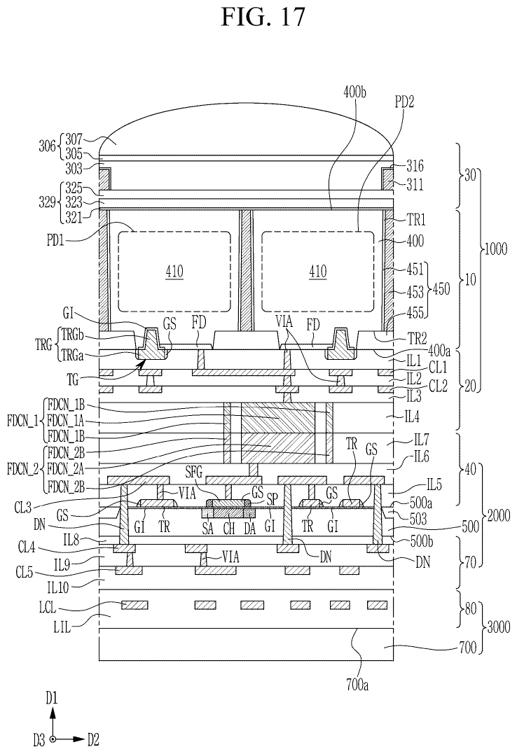

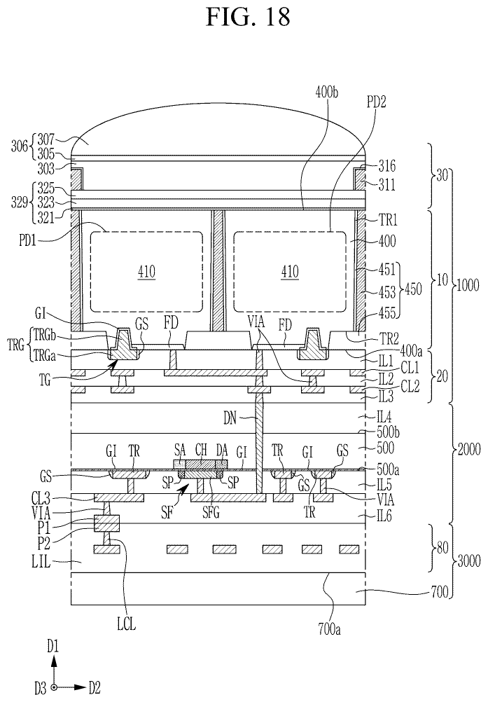

Hereinafter, in detail with reference to FIGS. 17 and 18, some transistors in the image sensor according to the present embodiment may be positioned on different substrates. That is, in an embodiment, the image sensor may include a first chip 1000, a second chip 2000, and a third chip 3000. In this case, the transistor included in the part indicated by A in the circuit diagram of FIG. 2 may be positioned on the first chip 1000, and the transistor included in the part indicated by B may be positioned on the second chip 2000. The floating diffusion region FD of the first chip 1000 may be connected to the second chip 2000 through a floating diffusion connection node FDCN_1 and FDCN_2 (see FIG. 17), and a detailed connection structure thereof will be described later. However, this is an example and all transistors shown in the circuit diagram of FIG. 2 may be positioned on the first chip 1000. In the present specification, an embodiment in which all transistors illustrated in the circuit diagram of FIG. 2 are positioned on the first chip 1000 will be described first, and then an embodiment in which some transistors are positioned on the second chip 2000 will be described.

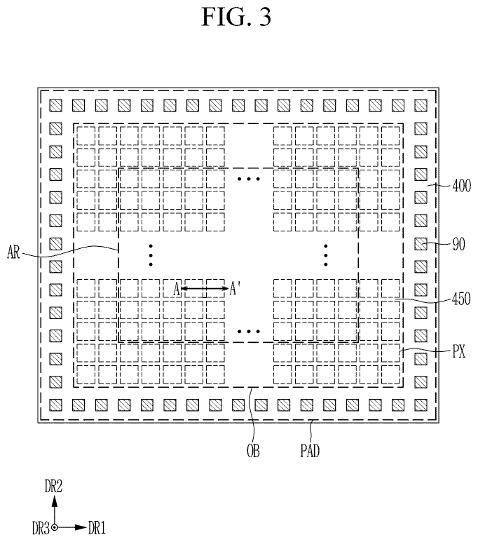

FIG. 3 is a plan view illustrating an image sensor according to embodiments of the present disclosure. FIG. 4 is a portion of a cross-section of one pixel PX of the image sensor according to the present embodiment. However, the descriptions of FIGS. 3 and 4 are only examples, and the present disclosure is not limited thereto.

Referring to FIGS. 3 and 4 at the same time, the image sensor according to the present embodiment may include a first chip 1000. The first chip 1000 may include a photoelectric conversion layer 10, a first wiring area 20, and a light transmission layer 30. The photoelectric conversion layer 10 may include a first substrate 400, a separation pattern 450, and a photoelectric conversion area 410 positioned in the first substrate 400. Light incident from the outside may be converted into an electrical signal in the photoelectric conversion area 410.

Referring to FIG. 3, the first substrate 400 may include a pixel array area AR, an optical black area OB, and a pad area PAD in a plane. The pixel array area AR may be positioned in a central area of the first substrate 400 in a plan view. The pixel array area AR may include a plurality of pixels PX. The pixel PX may output a photoelectric signal from incident light. The pixel PX may be arranged along a row parallel to the first direction DR1 and a column parallel to the second direction DR2. The pixel PX may include a plurality of photoelectric conversion areas.

The pad area PAD may be positioned at an edge portion of the first substrate 400 and may surround the pixel array area AR. A plurality of pad terminals 90 may be positioned in the pad area PAD. The pad terminals 90 may output an electrical signal generated in the pixel PX to the outside. Alternatively, an external electrical signal or voltage may be transmitted to the pixel PX through the pad terminal 90. Since the pad area PAD is positioned at the edge portion of the first substrate 400, the pad terminal 90 may be easily connected to the outside.

The optical black area OB may be disposed between the pixel array area AR and the pad area PAD of the first substrate 400. The optical black area OB may surround the pixel array area AR. The pixel positioned in the optical black area OB may include a dummy area instead of the photoelectric conversion area 410. The signal generated in the dummy area may be used as information for removing process noise.

Hereinafter, the stacked structure of the image sensor will be described in detail with reference to FIG. 4. The first chip 1000 may include a photoelectric conversion layer 10 and may be a layer generating a photoelectric signal. Although not specifically illustrated in FIG. 4, all transistors illustrated in FIG. 2 may be positioned on the first chip 1000. However, this is an example, and in another embodiment, some of the transistors shown in FIG. 2 may be positioned on the first chip 1000, and some may be positioned on the second chip (not shown) overlapping the first chip.

The first chip 1000 includes a first substrate 400. The first substrate 400 may include a first surface 400a and a second surface 400b. The second surface 400b may be opposite the first surface 400a. Light may be incident on the second surface 400b of the first substrate 400. The first wiring area 20 may be positioned on the first surface 400a of the first substrate 400, and the light transmission layer 30 may be positioned on the second surface 400b of the first substrate 400. The first substrate 400 may be a semiconductor substrate or a silicon-on-insulator SOI substrate. For example, the semiconductor substrate may include a silicon substrate, a germanium substrate, or a silicon-germanium substrate. The first substrate 400 may include a first conductivity type impurity. For example, the impurity of the first conductivity type may be a p-type impurity such as aluminum Al, boron B, indium In, and gallium Ga.

The first substrate 400 may include a separation pattern 450. The separation pattern 450 may partition a plurality of unit pixels and a plurality of photoelectric conversion areas within one pixel. FIG. 4 is a portion of a cross-section of one pixel, and two photoelectric conversion areas are illustrated in a cross-sectional view. However, this is a virtual cross-section for convenience of explanation, and the present disclosure is not limited thereto. That is, as illustrated in FIG. 2, one pixel may include four photoelectric conversion areas, and the number of photoelectric conversion areas included in one pixel may vary.

The first substrate 400 may include a photoelectric conversion area 410. The photoelectric conversion area 410 may perform the same functions and roles as the photovoltaic devices PD1, PD2, PD3, PD4 shown in FIG. 2. In FIG. 4, the first photovoltaic device PD1 and the second photovoltaic device PD2 are illustrated.

The photoelectric conversion area 410 may be an area doped with impurity of a second conductivity type in the first substrate 400. The second conductivity type impurity may have a conductivity type opposite to the first conductivity type impurity. The second conductivity type impurity may be an n-type impurity such as phosphorus, arsenic, bismuth, and antimony. For example, each photoelectric conversion area 410 may include a first area adjacent to the first surface 400a and a second area adjacent to the second surface 400b. There may be a difference in impurity concentration between the first area and the second area of the photoelectric conversion area 410. Accordingly, the photoelectric conversion area 410 may have a potential slope between the first surface 400a and the second surface 400b of the first substrate 400. However, as another example, the photoelectric conversion area 410 may not have a potential slope between the first surface 400a and the second surface 400b of the first substrate 400.

The first substrate 400 and the photoelectric conversion area 410 may constitute a photodiode. That is, a photodiode may be configured by a p-n junction between the first substrate 400 of the first conductivity type and the photoelectric conversion area 410 of the second conductivity type. The photoelectric conversion area 410 constituting the photodiode may generate and accumulate photo charge in proportion to the intensity of incident light.

Referring to FIG. 4, the separation pattern 450 may be positioned in the first substrate 400. The separation pattern 450 may have a grid structure in a plan view. The separation pattern 450 may be positioned between a plurality of photovoltaic devices PD1, PD2, PD3, PD4 included in one pixel while partitioning each pixel on a plane.

Referring to FIG. 4, the separation pattern 450 may be positioned in the first trench TR1 and the second trench TR2. The first trench TR1 and the second trench TR2 may penetrate the substrate 400 or may be recessed from the substrate 400 in some area of the first surface 400a of the first substrate 400. As shown in FIG. 4, the first trench TR1 may be formed deeper than the second trench TR2. The separation pattern 450 may extend from the first surface 400a of the first substrate 400 toward the second surface 400b. The separation pattern 450 may include a deep trench isolation DTI membrane and a shallow trench isolation STI membrane. The separation pattern 450 may penetrate the first substrate 400. A vertical height of the separation pattern 450 may be substantially the same as a vertical thickness of the first substrate 400. For example, the width of the separation pattern 450 may gradually decrease from the first surface 400a of the first substrate 400 toward the second surface 400b. However, this is an example and the present disclosure is not limited thereto.

The separation pattern 450 may include a first separation pattern 451, a second separation pattern 453, and a capping pattern 455. The first separation pattern 451 may be positioned along a sidewall of the first trench TR1. The first separation pattern 451 may include, for example, a silicon-based insulation material (e.g., silicon nitride, silicon oxide, or silicon oxynitride) or a high-k material (e.g., hafnium oxide or aluminum oxide). As another example, the first separation pattern 451 may include a plurality of layers, and each of the layers may include a different material. The first separation pattern 451 may have a refractive index lower than that of the first substrate 400. Accordingly, crosstalk phenomena between photoelectric conversion areas positioned on the first substrate 400 may be prevented or reduced.

The second separation pattern 453 may be positioned in the first separation pattern 451. For example, a sidewall of the second separation pattern 453 may be surrounded by the first separation pattern 451. The first separation pattern 451 may be positioned between the second separation pattern 453 and the first substrate 400. The second separation pattern 453 may be spaced apart from the first substrate 400 by the first separation pattern 451. Accordingly, during the operation of the image sensor, the second separation pattern 453 may be electrically separated from the first substrate 400. The second separation pattern 453 may include a crystalline semiconductor material, for example, polycrystalline silicon. For example, the second separation pattern 453 may further include a dopant, and the dopant may include a first conductivity type impurity or a second conductivity type impurity.

For example, the second separation pattern 453 may include a doped polycrystalline silicon. Alternatively, the second separation pattern 453 may include an undoped crystalline semiconductor material. For example, the second separation pattern 453 may include an undoped polycrystalline silicon. The term “undoped” may mean that no intentional doping process has been carried out. The dopant may include an n-type dopant and a p-type dopant. However, the second separation pattern 453 may include an insulating material.

The capping pattern 455 may be positioned on the lower surface of the second separation pattern 453.

The capping pattern 455 may be positioned in the second trench TR2 and may be disposed adjacent to the first surface 400a of the first substrate 400. The capping pattern 455 may include non-conductive material. For example, the capping pattern 455 may include a silicon-based insulating material (e.g., silicon nitride, silicon oxide, or silicon oxynitride) or a high-k material (e.g., hafnium oxide or aluminum oxide). Accordingly, the separation pattern 450 may limit and/or prevent photo charges generated by incident light incident on the photoelectric conversion area from being incident on another adjacent photoelectric conversion area by random drift. That is, the separation pattern 450 may limit and/or prevent crosstalk phenomenon between photoelectric conversion areas.

According to an embodiment, the first separation pattern 451 and the capping pattern 455 may include the same material, and in this case, it may be seen that the boundary between the first separation pattern 451 and the capping pattern 455 is not visually recognized and is connected as one.

Although FIG. 4 illustrates a configuration in which the separation pattern 450 and the first surface 400a of the first substrate 400 are positioned on the same plane, this is only an example, and the present embodiment is not limited thereto. For example, the separation pattern 450 and the first surface 400a of the first substrate 400 may not be coplanar. The separation pattern 450 may protrude or be recessed from the first surface 400a of the first substrate 400 to be positioned.

In addition, the upper surface of the separation pattern 450 is shown flat in FIG. 4, but this is an example, and the upper surface of the separation pattern 450 may include a curved surface. That is, the upper surface of the separation pattern 450 may have a structure depressed or protruding toward the substrate 400.

Referring to FIG. 4, the source follower transistor SF previously described in FIG. 2 may be positioned on the first surface 400a of the first substrate 400. Although not illustrated in FIG. 4, another transistor illustrated in FIG. 2 may also be positioned on the first surface 400a of the first substrate 400. The present embodiment is characterized by the structure of the source follower transistor SF, and hereinafter, the structure of the source follower transistor SF will be described.

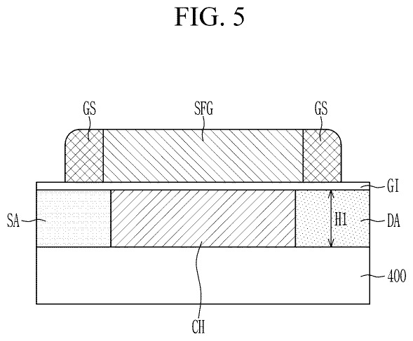

FIG. 5 is an enlarged view of the source follower transistor SF of FIG. 4.

Referring to FIGS. 4 and 5, the source follower transistor SF according to the present embodiment may include a source area SA, a drain area DA, a source area SA, and a channel area CH positioned between the drain area DA. In addition, the gate insulation layer GI may be positioned on the source area SA, the drain area DA, and the channel area CH, and the gate electrode SFG may be positioned on the gate insulation layer GI. The gate electrode SFG may be positioned to overlap the channel area CH, and the gate spacer GS may be positioned on both sides of the gate electrode SFG.

In the source follower transistor SF according to the present embodiment, the channel area CH and the drain area DA may be doped with the same conductivity type. In addition, the source area SA may be doped with a conductivity type different from that of the channel area CH and the drain area DA. For example, the source area SA may be doped with a first conductivity type dopant, and the channel area CH and the drain area DA may be doped with a second conductivity type dopant.

In this case, a doping concentration of the channel area CH may be lower than a doping concentration of the drain area DA. For example, the doping concentration of the channel area CH may be 1×10¹⁷ cm⁻³ to 1×10¹⁸ cm⁻³, and the doping concentration of the source area SA and the drain area DA may be 1×10¹⁹ cm⁻³ to 1×10²⁰ cm⁻³.

The first conductivity type dopant may be a p-type impurity such as aluminum Al, boron B, indium In, and gallium Ga. The second conductivity type dopant may be an n-type impurity such as phosphorus, arsenic, bismuth, and antimony.

That is, the source follower transistor according to the present embodiment may include a P-doped source area SA, an N-doped channel area CH, and an N-doped drain area DA. Alternatively, the source follower transistor according to another embodiment may include an N-doped source area SA, a P-doped channel area CH, and a P-doped drain area DA.

In this way, the source follower transistor SF according to the present embodiment may be a tunneling field effect transistor in which the channel area CH is doped with a conductivity type dopant such as the drain area DA, and the source area SA is doped with a different conductivity type dopant. Such a tunneling field effect transistor may have a high voltage gain Av while reducing noise due to a buried channel. A detailed effect thereof will be described later.

Referring to FIGS. 4 and 5, a gate spacer GS may be positioned on a side surface of the gate electrode SFG. The gate spacer GS may include an insulating material, such as silicon nitride, silicon carbide nitride, or silicon oxynitride.

In the source follower transistor according to the present embodiment, the doping depth H1 from the first surface 400a of the first substrate 400 in the channel area CH, the source area SA, and the drain area DA may be in a range of 20 nm to 100 nm. When the doping depth is less than 20 nm, the gate insulation layer GI and the current path are adjacent to each other, so that noise due to the dangling bond of the gate insulation layer GI may occur. In addition, when the doping depth exceeds 100 nm, the distance between the gate electrode SFG and the current path increases, and thus the control by the gate electrode SFG may decrease.

Referring back to FIG. 4, the first wiring area 20 is positioned on the first surface 400a of the substrate 400, and may include a plurality of insulation layers IL1, IL2, IL3, a plurality of wiring layers CL1 and CL2, and at least one via VIA. The via VIA may connect two of the wiring layers CL1 and CL2 to each other.

The insulation layer may include a first insulation layer IL1, a second insulation layer IL2, and a third insulation layer IL3.

The first insulation layer IL1 may cover the first surface 400a of the substrate 400. The second insulation layer IL2 may be positioned on the first insulation layer IL1. The third insulation layer IL3 may be positioned on the second insulation layer IL2.

The first to third insulation layer (IL1, IL2, IL3) may include non-conductive material. For example, the first to third insulation layers IL1, IL2, IL3 may include an insulating material. The first to third insulation layers IL1, IL2, IL3 may include a silicon-based insulation material such as silicon oxide, silicon nitride, or silicon oxynitride.

The first wiring area 20 may include a first wiring layer CL1 and a second wiring layer CL2. The first wiring layer CL1 may be positioned in the second insulation layer IL2. The second wiring layer CL2 may be positioned in the third insulation layer IL3.

A plurality of vias VIA may be positioned in the first insulation layer IL1, the second insulation layer IL2, and the third insulation layer IL3. The via VIA may connect the floating diffusion FD, the first wiring layer CL1, and the second wiring layer CL2 to each other.

The first wiring layer CL1, the second wiring layer CL2, and the via VIA may include metal material. For example, the first wiring layer CL1, the second wiring layer CL2, and the via VIA may include copper Cu.

In addition, the image sensor according to the present embodiment may include a light transmission layer 30. The light transmission layer 30 may include an insulation structure 329, a color filter 303, and a microlens unit 306. The light transmission layer 30 may condense and filter light incident from the outside, providing the light to the photoelectric conversion area 410.

A color filter 303 may be positioned on the second surface 400b of the substrate 400. The color filter 303 may be disposed in one pixel PX, respectively. In each pixel PX, the color filter 303 may include primary color filters. The color filter 303 may include a first color filter, a second color filter, and a third color filter having different colors from one another. For example, the first color filter, the second color filter, and the third color filter may include green, red, and blue color filters, respectively. The first color filter, the second color filter, and the third color filter may be arranged in a Bayer pattern manner. As another example, the first color filter, the second color filter, and the third color filter may include a color such as cyan, magenta, or yellow.

An insulation structure 329 may be positioned between the second surface 400b of the substrate 400 and the color filter 303. The insulation structure 329 may limit and/or prevent reflection of light so that light incident on the second surface 400b of the substrate 400 may smoothly reach the photoelectric conversion area 410. The insulation structure 329 may be referred to as an anti-reflection structure.

The insulation structure 329 may include a first fixed charge layer 321, a second fixed charge layer 323, and a planarization layer 325 sequentially stacked on the second surface 400b of the substrate 400. Each of the first fixed charge layer 321, the second fixed charge layer 323, and the planarization layer 325 may include a material different from each other. The first fixed charge layer 321 may include any one of aluminum oxide, tantalum oxide, titanium oxide, and hafnium oxide. The second fixed charge layer 323 may include any one of aluminum oxide, tantalum oxide, titanium oxide, and hafnium oxide. For example, the first fixed charge layer 321 may include aluminum oxide, the second fixed charge layer 323 may include hafnium oxide, and the planarization layer 325 may include silicon oxide. Although not shown, in another embodiment, an anti-reflection layer (not shown) may be interposed between the second fixed charge layer 323 and the planarization layer 325. The anti-reflection layer may include silicon. The anti-reflection layer may include silicon nitride.

The microlens unit 306 may be positioned on the color filter 303. The microlens unit 306 may include a flat portion 305 in contact with the color filter 303 and a microlens 307 positioned on the flat portion 305. The flat portion 305 may include, for example, an organic material. As another example, the flat portion 305 may include an inorganic material such as silicon oxide or silicon oxynitride. The microlens 307 may have a convex shape to condense incident light. Each microlens 307 may vertically overlap the photoelectric conversion area 410. The shape of the lens may vary. In FIG. 4, for convenience of description, one microlens 307 is shown in a shape overlapping two photoelectric conversion areas 410 in a cross section. However, on a plane, one microlens 307 may be positioned in a shape overlapping the four photoelectric conversion areas 410. However, this is only an example, and the number of microlenses 307 positioned in one pixel PX may vary.

The light transmission layer 30 may further include a Bayer pattern 311 and a passivation layer 316. The Bayer pattern 311 may be positioned between the color filters 303 adjacent to each other to separate them from each other. The Bayer pattern 311 may be positioned on the insulation structure 329. For example, the Bayer pattern 311 may have a grid structure. The Bayer pattern 311 may include a material having a lower refractive index than the color filter 303. The Bayer pattern 311 may include an organic material. For example, the Bayer pattern 311 may be a polymer layer including silica nanoparticles. Since the Bayer pattern 311 has a low refractive index, the amount of light incident on the photoelectric conversion area 410 may be increased, and crosstalk between pixels PX may be reduced. That is, the light-receiving efficiency may be increased in each photoelectric conversion area 410, and the signal noise ratio SNR characteristics may be improved.

The passivation layer 316 may cover the surface of the Bayer pattern 311 with a substantially uniform thickness. The passivation layer 316 may include, for example, at least one single layer or multiple layers of an aluminum oxide layer and a silicon carbide oxide layer. The passivation layer 316 may protect the color filter 303 and perform a moisture absorption function. Although the passivation layer 316 is depicted as separate structures in FIG. 4, in one embodiment, the passivation layer 316 may be connected as one between neighboring Bayer pattern 311.

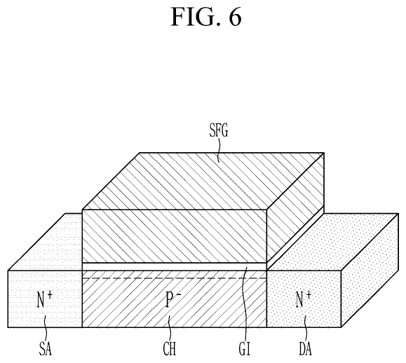

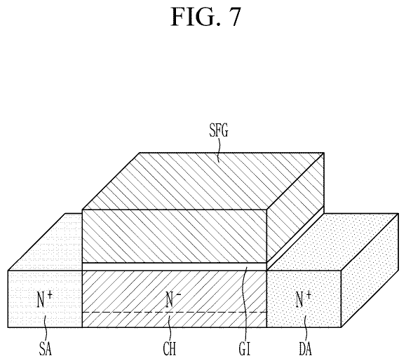

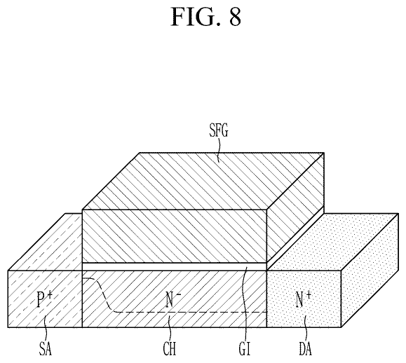

Then, effects of the source follower transistor and the image sensor including the same according to the present embodiment will be described in detail with reference to the drawings. FIG. 6 schematically illustrates the structure of a general source follower transistor CSF, FIG. 7 schematically illustrates the structure of a source follower transistor BCSF with a buried channel, and FIG. 8 schematically illustrates the structure of a tunneling source follower transistor TSF including a tunneling mechanism as a source follower transistor according to the present embodiment. The structure of the source follower transistors of FIGS. 6 to 8 is the same as that described above with reference to FIG. 5, and in each drawing, only the conductivity type of the source area SA, the channel area CH, and the drain area DA is different. That is, each source follower transistor may include a source area SA, a channel area CH, a drain area DA, and a gate electrode SFG overlapping the channel area CH with the gate insulation layer GI interposed therebetween. For convenience of description, a conductivity type doped into the source area SA, the channel area CH, and the drain area DA is described in FIGS. 6 to 8.

Referring to FIG. 6, in the case of a general source follower transistor CSF, the source area SA and the drain area DA may be doped with dopants of the same conductivity type, and the channel area CH may be doped with dopants of a different conductivity type from the source area SA and the drain area DA. That is, as illustrated in FIG. 6, the source area SA and the drain area DA may be doped with an N-type dopant, and the channel area CH may be doped with a P-type dopant. In this case, the doping concentration of the channel area CH may be lower than the doping concentrations of the source area SA and the drain area DA.

In the general source follower transistor CSF, a current path is formed adjacent to the gate electrode SFG. In FIG. 6, the approximate current path is shown by a dotted line. As shown in FIG. 6, the current path of the channel area CH in the general source follower transistor CSF may be positioned adjacent to the gate insulation layer GI. Therefore, a non-uniform charge trap may occur due to the dangling bond formed at the interface of the gate insulation layer GI. A plurality of dangling bonds is positioned at the interface between the gate insulation layer GI and the substrate, and such dangling bonds may non-uniformly trap charges passing through the channel area CH. Such a non-uniform charge trap may cause noise during operation of the image sensor.

Accordingly, noise may be reduced by physically dropping the current path from the gate insulation layer GI through the buried channel. FIG. 7 illustrates a source follower transistor BCSF having a buried channel. Referring to FIG. 7, in the case of the buried channel source follower transistor BCSF, the source area SA, the channel area CH, and the drain area DA may be doped with dopants of the same conductivity type. That is, as shown in FIG. 7, the source area SA, the channel area CH, and the drain area DA may be doped with an N-type dopant. However, this is an example, and the source area SA, the channel area CH, and the drain area DA may be doped with a P-type dopant.

The doping concentration of the channel area CH may be lower than the doping concentrations of the source area SA and the drain area DA. That is, as described above, the doping concentration of the channel area CH may be ×10¹⁷ cm⁻³ to 1×10¹⁸ cm⁻³, and the doping concentration of the source area SA and the drain area DA may be 1×10¹⁹ cm⁻³ to 1×10²⁰ cm⁻³.

In the case of FIG. 7, the source area SA, the channel area CH, and the drain area DA are non-junction field-effect transistors doped with dopants of the same conductivity type. Due to this non-junctional structure, the device operates in the depletion area to form a buried channel, and the buried channel physically drops the current path from the gate insulation layer GI. The current path is shown in a dotted line in FIG. 7. As illustrated in FIG. 7, the current path is positioned apart from the gate insulation layer GI. Therefore, the influence of the dangling bond positioned at the interface of the gate insulation layer GI is reduced, and non-uniform charge traps can be limited and/or minimized, thereby reducing noise.

However, in the case of a transistor having such a buried channel, since the current path is separated from the gate electrode SFG, the gate control ability is reduced. This may cause a low voltage gain Av.

However, in the source follower transistor according to this example, the channel area CH and the drain area DA were doped with the same conductivity type, and the source area SA was doped with a different conductivity type. Thus, while reducing noise due to buried channel, voltage gain Av properties can be improved with band-to-band tunneling as the main electron transport mechanism.

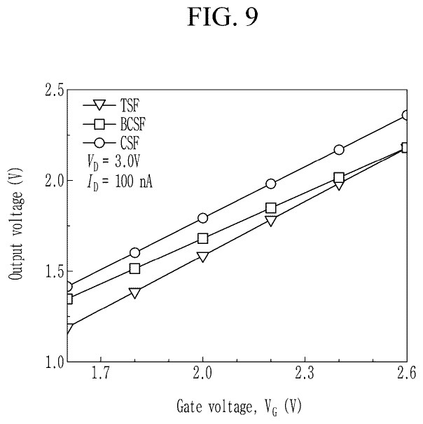

Referring to FIG. 8, the channel area CH and the drain area DA of the tunneling source follower transistor TSF according to the present embodiment are doped with the same conductivity type. In addition, the source area SA is doped with a different conductivity type. That is, as illustrated in FIG. 9, the source area SA may be doped with a P-type dopant, and the channel area CH and the drain area DA may be doped with an N-type dopant. However, this is an example, and the source area SA may be doped with an N-type dopant, and the channel area CH and the drain area DA may be doped with a P-type dopant.

The doping concentration of the channel area CH may be lower than the doping concentrations of the source area SA and the drain area DA. That is, as described above, the doping concentration of the channel area CH may be 1×10¹⁷ cm⁻³ to 1×10¹⁸ cm⁻³, and the doping concentration of the source area SA and the drain area DA may be 1×10¹⁹ cm⁻³ to 1×10²⁰ cm⁻³.

In FIG. 8, the current path of the source follower transistor according to the present embodiment is shown by a dotted line. As shown in FIG. 8, the current path of the source follower transistor according to the present embodiment may have an L shape. In the tunneling source follower transistor according to the present embodiment shown in FIG. 8, band-to-band tunneling occurs in the conduction band of the channel area CH from the valence band of the source area SA and is local. In addition, the electric field is regulated by gate potential, resulting in tunneling at most surfaces. Therefore, the current path is positioned adjacent to the gate insulation layer GI at the boundary between the source area SA and the channel area CH, and the current path is formed away from the gate insulation layer GI at the boundary between the channel area CH and the drain area DA. Accordingly, the source follower transistor according to the present embodiment may form an alphabet L-type buried channel area, unlike the source follower transistor BCSF having an existing buried channel area. Therefore, it is possible to secure the gate control capability of the gate electrode SFG while reducing noise by minimizing non-uniform charge traps.

Then, the noise reduction effect and voltage gain improvement effect of the source follower transistor according to the present embodiment will be described below through specific experimental data.

FIG. 9 illustrates an output voltage under a constant drain voltage (V_{D}=3.0V) and a constant drain current (I_{D}=100 nA) condition with respect to transistors of FIGS. 6 to 8. In FIGS. 9 to 16, a general source follower transistor of FIG. 6 is represented by CSF, a buried channel source follower transistor of FIG. 7 is represented by BCSF, and a tunneling source follower transistor of FIG. 9 is represented by TSF.

Referring to FIG. 9, it is confirmed that the output voltage of the tunneling source follower transistor TSF according to the present embodiment was the lowest under the condition of the drain voltage V_{D} of 3.0 V and the drain current I_{D} of 100 nA, the output voltage of the buried channel source follower transistor BCSF according to the embodiment of FIG. 7 was the middle, and the output voltage of the general source follower transistor CSF according to the embodiment of FIG. 6 was the highest.

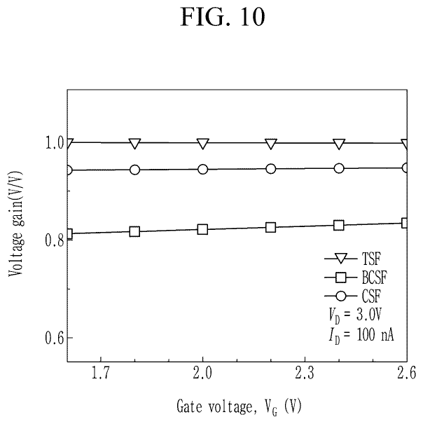

FIG. 10 illustrates a voltage gain under a constant drain voltage (V_{D}=3.0V) and a constant drain current (I_{D}=100 nA) condition for each transistor of FIGS. 6 to 8. The voltage gain Av is a value obtained by dividing the output voltage into a gate voltage. Referring to FIG. 10, it is confirmed that the voltage gain of the tunneling source follower transistor TSF according to the present embodiment is the highest. That is, as shown in FIG. 10, the voltage gain of the tunneling source follower transistor TSF according to the present embodiment is the highest, and the voltage gain of the buried tunnel source follower transistor BCSF of FIG. 7 is the lowest. The voltage gain of the general source follower transistor CSF of FIG. 6 is found between the tunneling source follower transistor TSF and the buried tunnel source follower transistor BCSF.

The source follower transistor BCSF with a buried channel has a lower voltage gain (~0.8V/V) than the general source follower transistor CSF due to reduced gate control ability due to the formation of a buried channel. However, it was confirmed that the tunneling source follower transistor TSF according to this embodiment has a high voltage gain (~1.0 V/V) despite forming a buried channel area. This is because, as described above, the tunneling source follower transistor TSF according to the present embodiment flows current by band-to-band tunneling in the source area SA and the channel area CH, and the current path is positioned adjacent to the gate insulation layer GI, thereby maintaining gate control capability. Therefore, it is possible to have a higher voltage gain compared to a buried tunnel source follower transistor BCSF having the same buried channel.

Then, hereinafter, an effect of improving the voltage gain of the tunneling source follower transistor TSF according to the present embodiment will be described in another method.

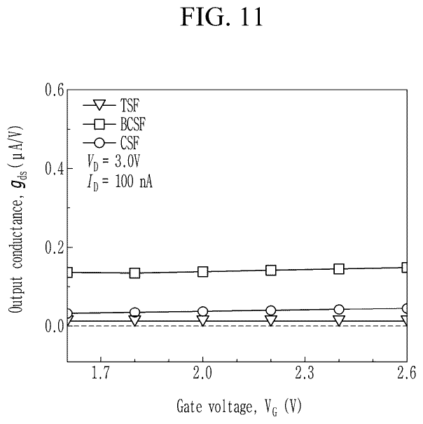

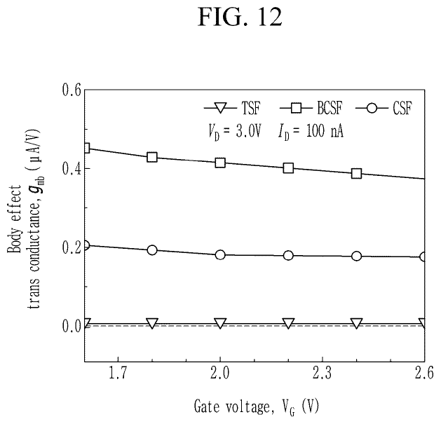

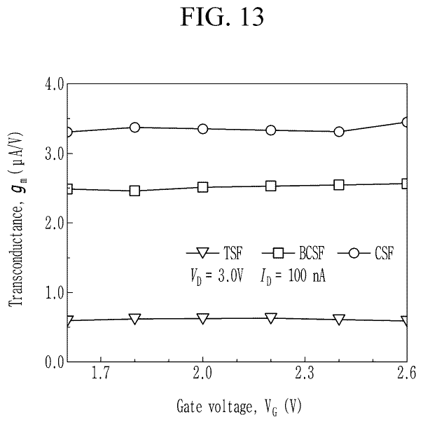

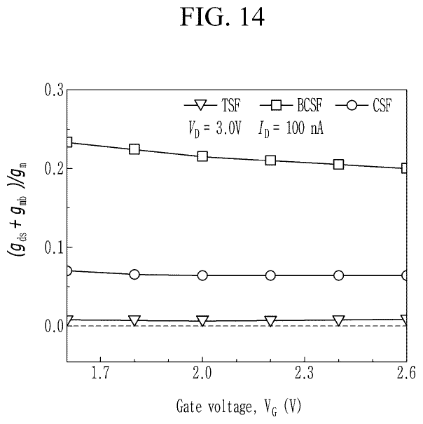

FIG. 11 is an output conductance g_{ds} under a constant drain voltage V_{D}=3.0V and a constant drain current (I_{D}=100 nA) condition for each transistor of FIGS. 6 to 8. FIG. 12 is body effect trans conductance gmb under a constant drain voltage (V_{D}=3.0V) and a constant drain current (I_{D}=100 nA) condition for each transistor of FIGS. 6 to 8. FIG. 13 is a trans conductance gm under a constant drain voltage (V_{D}=3.0V) and a constant drain current (I_{D}=100 nA) condition. FIG. 14 is a sum (gds+gmb)/gm of output conductance and body effect trans conductance relative to trans conductance for each transistor of FIGS. 6 to 8.

That is, FIGS. 11 to 13 are values measured to derive the sum ((gds+gmb)/gm) of the output conductance and the body effect trans conductance compared to the trans conductance of FIG. 14.

In the tunneling source follower transistor TSF according to the present embodiment, the band-to-band tunneling generation area occurs on the surface of the boundary between the source area SA and the channel area CH. Therefore, the effect of the drain area DA and the short channel effect are smaller than those of the conventional buried channel source follower transistor BCSF. Therefore, as shown in FIG. 11, the tunneling source follower transistor TSF according to the present embodiment has a low output conductance.

In addition, the tunneling source follower transistor TSF according to this embodiment has a small body effect because the source area SA doped with a P-type dopant limits and/or suppresses the change in the depletion layer. Therefore, as shown in FIG. 12, the tunneling source follower transistor TSF according to the present embodiment has a low body effect trans conductance,

Referring to FIG. 13, the trans conductance gm of the tunneling source follower transistor TSF according to the present embodiment is lower than the trans conductance gm of the buried channel transistor BCSF or the general source follower transistor CSF.

However, referring to FIG. 14 based on the data of FIGS. 11 to 13, the sum of the output conductance and the body effect trans conductance ((gds+gmb)/gm) compared to the trans conductance of the tunneling source follower transistor TSF according to the present embodiment was found to be lower than the sum of the output conductance and the body effect trans conductance ((gds+gmb)/gm) compared to the trans conductance of the buried channel transistor BCSF or the general source follower transistor CSF.

That is, referring to FIG. 14, it was confirmed that the sum of the output conductance and the body effect trans conductance ((gds+gmb)/gm) compared to the trans conductance was the lowest for the tunneling source follower transistor TSF according to the present embodiment, and the highest for the buried transistor BCSF according to the embodiment of FIG. 7.

The voltage gain can be expressed as shown in the following equation 1.

$${A}_{v} = \frac{1}{1 + ( \frac{{g}_{ds} + {g}_{mb}}{{g}_{m}} )} \qquad [ Equation 1 ]$$

That is, according to Equation 1, the lower the sum (gds+gmb)/gm) of the output conductance and the body effect trans conductance compared to the trans conductance, the higher the voltage gain. As can be seen in FIG. 14, it was confirmed that the tunneling source follower transistor TSF according to the present embodiment has the lowest trans conductance-to-output conductance and the sum of body effect trans conductance ((gds+gmb)/gm), and thus has the highest voltage gain.

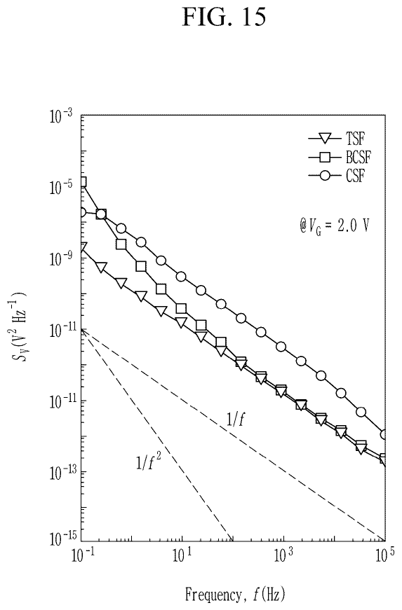

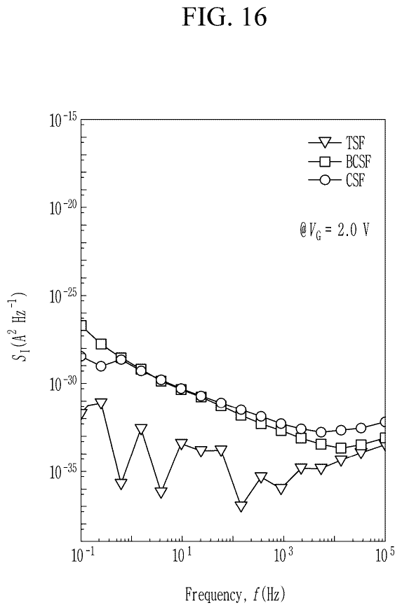

FIG. 15 is the input-referred voltage noise spectral density SV for the transistors of FIGS. 6 to 8 under conditions of a constant drain voltage (V_{D}=3.0 V) and a constant drain current (I_{D}=100 nA). FIG. 16 is the input-referred current noise spectral density (SI) for the transistors of FIG. 6 to 8 under conditions of a constant drain voltage (V_{D}=3.0 V) and a constant drain current (I_{D}=100 nA).

Referring to FIG. 15, it was confirmed that a tunneling source follower transistor TSF according to one embodiment has an input-referred voltage noise spectral density that is 10 times lower overall than a general source follower transistor CSF and a buried channel source follower transistor BCSF. This is because, as described above, in the tunneling source follower transistor TSF according to the present embodiment, a high electric field is formed for band-to-band tunneling in the area where the channel is in contact with the gate insulation layer, and a high electric field accelerates the charge carrier to reduce the effect from the interface trap.

In addition, referring to FIG. 16, current noise was generally low in all transistors, but even in the case of current noise, it was confirmed that the tunneling source follower transistor TSF according to this embodiment exhibited lower current noise than the general source follower transistor CSF and the buried channel source follower transistor BCSF.

In the above, an embodiment in which the source follower transistor SF is positioned on the first chip 1000 has been described. However, in another embodiment, the image sensor may include a first chip 1000, a second chip 2000, and a third chip 3000, and the source follower transistor SF may be positioned on the second chip 2000.

FIG. 17 is the same cross-section as FIG. 4 for another embodiment. Referring to FIG. 17, an image sensor according to the present embodiment includes a first chip 1000, a second chip 2000, and a third chip 3000.

Most of the descriptions of the first chip 1000 are the same as those described in FIG. 4, and thus will be omitted. However, referring to FIG. 17, the transfer transistor TG is positioned instead of the source follower transistor on the first surface 400a of the first substrate 400. The transfer transistor TG may be electrically connected to photoelectric conversion area 410. The transfer transistor TG may include a transfer gate TRG and a floating diffusion region FD. The transfer gate TRG may include a first portion TGa positioned on the first surface 400a of the first substrate 400 and a second portion TRGb extending from the first portion TRGa into the first substrate 400. The maximum width of the first portion TRGa in the second direction D2 may be greater than the maximum width of the second portion TRGb in the second direction D2. The floating diffusion region FD may be adjacent to one side of the transfer gate TRG. The floating diffusion region FD may have a second conductivity type (e.g., n-type) opposite that of the first substrate 400.

A gate insulation layer GI may be positioned between the transfer gate TRG and the first substrate 400. A gate spacer GS may be positioned on a sidewall of the transfer gate TRG. The gate spacer GS may include silicon nitride, silicon carbide nitride, or silicon oxynitride. A plurality of floating diffusion regions FD connected to different transfer transistor TG may be connected through a via VIA, a first wiring layer CL1, or the like.

In addition, the first chip 1000 may further include a fourth insulation layer IL4. The first floating diffusion connection node FDCN_1 may be positioned in the fourth insulation layer IL4. The first floating diffusion connection node FDCN_1 may include a main connection part FDCN_1A and a shielding part FDCN_1B. The shielding part FDCN_1B may be positioned at an edge of the main connection part FDCN_1A, and may be positioned in an area narrower than that of the main connection part FDCN_1A. The shielding part FDCN_1B may limit and/or prevent interference between the floating diffusion connection node of the neighboring pixel PX. The main connection part FDCN_1A of the first floating diffusion connection node FDCN_1 is connected to wirings of the first wiring layer CL1 and the second wiring layer CL2, but the shielding part FDCN_1B of the first floating diffusion connection node FDCN_1 may not be connected to the wiring of the first wiring layer CL1 and the wiring of the second wiring layer CL2. In addition, the main connection part FDCN_1A of the first floating diffusion connection node FDCN_1 is positioned in a separate island shape for each pixel, but the shielding part FDCN_1B may be positioned connected to neighboring pixels. For example, the shielding part FDCN_1B may be positioned in a linear shape extending in one direction on a plane. A separate voltage may be applied to the shielding part FDCN_1B. However, this is an example, and according to an embodiment, the shielding part FDCN_1B may be omitted.

As shown in FIG. 17, one surface of the first floating diffusion connection node FDCN_1 is exposed without being covered with the fourth insulation layer IL4. Therefore, as will be described later, it can contact the second floating diffusion connection node FDCN_2 positioned in the second chip 2000.

Then, the second chip 2000 will be described below. The second chip 2000 may include a second substrate 500, a second wiring area 40, and a third wiring area 70.

The second substrate 500 may include a first surface 500a and a second surface 500b facing each other. The second wiring area 40 may be positioned on the first surface 500a of the second substrate 500, and the third wiring area 70 may be positioned on the second surface 500b of the second substrate 500.

The second substrate 500 may be a semiconductor substrate or a silicon insulator SOI substrate. The semiconductor substrate may include, for example, a silicon substrate, a germanium substrate, or a silicon-germanium substrate. The second substrate 500 may include a first conductivity type impurity. For example, the impurity of the first conductivity type may include p-type impurity such as aluminum Al, boron B, indium In, and/or gallium Ga.

The first surface 500a of the second substrate 500 may be positioned to face the first surface 400a of the first substrate 400.

The reset transistor RG, the dual conversion gain transistor DCG, the source follower transistor SF, and the selection transistor SEL described in FIG. 2 may be positioned on the first surface 500a of the second substrate 500. In FIG. 17, the reset transistor, the dual conversion transistor, and the selection transistor are illustrated as a transistor TR. The description of the shape of the source follower transistor SF is the same as described in advance and thus is omitted. That is, in the source follower transistor SF, the channel area CH and the drain area DA are doped with the same conductivity type, and the source area SA is doped with a different conductivity type from the channel area CH and the drain area DA.

A gate insulation layer GI may be interposed between the second substrate 500 and the gate electrode of each of the reset transistor, the dual conversion transistor, and the selection transistor. A gate spacer GS may be positioned on a sidewall of each of the gate electrodes. The gate spacer GS may include silicon nitride, silicon carbide nitride, or silicon oxynitride.

A fifth insulation layer IL5, a sixth insulation layer IL6, a seventh insulation layer IL7, a third wiring layer CL3, a plurality of vias VIA, and a second floating diffusion connection node FDCN_2 may be positioned on the first surface 500a of the second substrate 500.

The fifth insulation layer IL5, the sixth insulation layer IL6, and the seventh insulation layer IL7 may include a non-conductive material. For example, the fifth insulating layer IL5, the sixth insulating layer IL6, and the seventh insulating layer IL7 may include a silicon-based insulating material such as silicon oxide, silicon nitride, or silicon oxynitride.

The third wiring layer CL3, the via VIA, and the second floating diffusion connection node FDCN_2 may include a metal material. For example, the third wiring layer CL3, the via VIA, and the second floating diffusion connection node FDCN_2 may include copper Cu.

The third wiring layer CL3 may be positioned in the sixth insulation layer IL6. At least one of the wiring of the third wiring layer CL3 and the gate electrode of the reset transistor RG shown in FIG. 2, the gate electrode of the dual conversion gain transistor DCG, the gate electrode of the source follower transistor SF, and the gate electrode of the selection transistor SEL may be connected by a via VIA. In addition, one or more electrodes of the third wiring layer CL3, the reset transistor RG, the dual conversion gain transistor DCG, the source follower transistor SF, and the selection transistor SEL may be connected through vias.

The second floating diffusion connection node FDCN_2 may be positioned in the seventh insulation layer IL7. The second floating diffusion connection node FDCN_2 may include a main connection part FDCN_2A and a shielding part FDCN_2B. The shielding part FDCN_2B may be positioned at an edge of the main connection part FDCN_2A, and may be positioned in an area narrower than that of the main connection part FDCN_2A. The shielding part FDCN_2B may limit and/or prevent interference between the floating diffusion connection node of the neighboring pixel PX. The main connection part FDCN_2A of the second floating diffusion connection node FDCN_2 is connected to the wiring of the third wiring layer CL3, but the shielding part FDCN_2B of the second floating diffusion connection node FDCN_2 may not be connected to the wiring of the third wiring layer CL3. The main connection part FDCN_2A of the second floating diffusion connection node FDCN_2 is positioned in an island shape separated for each pixel, but the shielding part FDCN_2B may be positioned to be connected to neighboring pixels. For example, the shielding part FDCN_2B may be positioned in a linear shape extending in one direction on a plane. A separate voltage may be applied to the shielding part FDCN_2B. However, this is an example, and according to an embodiment, the shielding part FDCN_2B may be omitted.

As shown in FIG. 17, one surface of the second floating diffusion connection node FDCN_2 is not covered by the seventh insulation layer IL7 but is exposed. Therefore, as shown in FIG. 17, the first floating diffusion connection node FDCN_1 positioned in the first chip 1000 and the second floating diffusion connection node FDCN_2 positioned in the second chip 2000 may contact each other.

Referring to FIG. 17, the second chip 2000 may include a deep node DN penetrating the second substrate 500. The deep node DN may include a metal, for example, copper Cu. However, these materials are only examples, and may also contain other metal materials.

The deep node DN is positioned through the second substrate 500, and one end of the deep node DN may be positioned on the first surface 500a and the other end may be positioned on the second surface 500b. In the present specification, the expression positioned on a certain surface is not limited to being positioned in contact with the surface, but includes being positioned in a form that is not in contact with or protruding from the surface. That is, as shown in FIG. 17, one end of the deep node DN may be positioned to protrude from the first surface 500a, and the other end may be positioned to protrude from the second surface 500b.

Therefore, as shown in FIG. 17, one end of the deep node DN may be in contact with the wiring of the third wiring layer CL3. In addition, the other end of the deep node DN may be in contact with the fourth wiring layer CL4 positioned on the second surface 500b of the second substrate 500.

An eighth insulation layer IL8, a ninth insulation layer IL9, a tenth insulation layer IL10, a fourth wiring layer CL4, a fifth wiring layer CL5, and a via VIA may be positioned on the second surface 500b of the second substrate 500.

The eighth insulation layer IL8, the ninth insulation layer IL9, and the tenth insulation layer IL10 may include non-conductive material. For example, the eighth insulation layer IL8, the ninth insulation layer IL9, and the tenth insulation layer IL10 may include a silicon-based insulation material such as silicon oxide, silicon nitride, or silicon oxynitride.

The fourth wiring layer CL4, the fifth wiring layer CL5, and the via VIA may include metal material. For example, the fourth wiring layer CL4, the fifth wiring layer CL5, and the via VIA may include copper Cu. However, these materials are only examples, and the present disclosure is not limited thereto.

The fourth wiring layer CL4 may be positioned in the ninth insulation layer IL9. The fifth wiring layer CL5 may be positioned in the tenth insulation layer IL10. The fourth wiring layer CL4 and the fifth wiring layer CL5 may be connected through a via VIA.

The deep node DN may be positioned on the fifth insulation layer IL5, the second substrate 500, and the eighth insulation layer IL8. The deep node DN is positioned to penetrate the second substrate 500, and may connect at least one of the reset transistor RG, the dual conversion gain transistor DCG, the source follower transistor SF, and the selection transistor SEL positioned on the first surface 500a of the second substrate 500 to the fourth wiring layer CL4 and the fifth wiring layer CL5 positioned on the second surface 500b of the second substrate 500.

That is, the wiring positioned in the fourth wiring layer CL4 and the fifth wiring layer CL5 may be connected to the gate electrode of the reset transistor RG, the gate electrode of the dual conversion gain transistor DCG, and the gate electrode of the selection transistor SEL to transmit a gate signal. In addition, a power supply voltage Vpix may be applied by being connected to the source electrode of the reset transistor RG and the source follower transistor SF. In addition, the output wiring Vout positioned in the fourth wiring layer CL4 or the fifth wiring layer CL5 may be connected to the drain electrode of the selection transistor SEL. However, according to an embodiment, the deep node DN may be omitted. In this case, the wiring connected to the transistor positioned on the second substrate 500 may be positioned on the first surface 500a of the second substrate 500.

Also, referring to FIG. 17, the second chip 2000 may be connected to the third chip 3000. The third chip 3000 may include a third substrate 700 and a fourth wiring area 80. A transistor (not shown) constituting a logic circuit may be positioned on the first surface 700a of the third substrate 700, and a plurality of wirings LCL may be positioned in the fourth wiring area 80. The fourth wiring area 60 includes an insulation layer LIL, and a plurality of wiring LCL may be connected to the wiring of the second chip 2000 through vias (not shown).

The third substrate 700 may be a semiconductor substrate or a silicon-on-insulator SOI substrate. The semiconductor substrate may include, for example, a silicon substrate, a germanium substrate, or a silicon-germanium substrate. The third substrate 700 may include a first conductivity type impurity. For example, the impurity of the first conductivity type may include p-type impurity such as aluminum Al, boron B, indium (In), and/or gallium Ga.

In addition, FIG. 17 is an embodiment in which the first surface 400a of the first substrate 400 and the first surface 500a of the second substrate 500 face each other, but in another embodiment, the first surface 400a of the first substrate 400 and the second surface 500b of the second substrate 500 may face each other.

FIG. 18 is the same cross-section as FIG. 17 for another embodiment. Referring to FIG. 18, the first surface 400a of the first substrate 400 and the second surface 500b of the second substrate 500 may be positioned to face each other. As shown in FIG. 18, a reset transistor RG, a dual conversion gain transistor DCG, a source follower transistor SF, and a selection transistor SEL are positioned on the first surface 500a of the second substrate 500, and the floating diffusion region FD of the first chip 1000 may be connected through a deep node DN penetrating the second substrate 500.

Referring to FIG. 18, the description of the first chip 1000 and the third chip 3000 is the same as described above. A detailed description of the same elements will be omitted.

In FIG. 18, a fourth insulation layer IL4 may be positioned on the second surface 500b of the second substrate 500. Also, a fifth insulation layer IL5 and a sixth insulation layer IL6 may be positioned on the first surface 500a of the second substrate 500. A via VIA may be positioned in the fifth insulation layer IL5, and the via VIA may be connected to each transistor. Also, the third wiring layer CL3 may be positioned on the sixth insulation layer IL6. The third wiring layer CL3 may be connected to each of the transistors and the first pad P1 through a via VIA. The second pad P2 may be positioned on the third chip 3000, and the first pad P1 and the second pad P2 may be in direct contact with each other. The first pad P1 and the second pad P2 may include copper, but are not limited thereto.

However, the structure described above is an example, and the present disclosure is not limited thereto. That is, the image sensor according to the present embodiment is not limited to the structures shown in FIGS. 17 and 18 as long as a transfer transistor is positioned in the first chip 1000, a reset transistor RG, a dual conversion gain transistor DCG, a source follower transistor SF, and a selection transistor SEL are positioned in the second chip 2000, the channel area CH and the drain area DA of the source follower transistor SF are doped with the same conductivity type, and the source area SA is doped with a different conductivity type from the channel area CH and the drain area DA.

As described above, in the image sensor including the source follower transistor according to the present embodiment, the channel area CH and the drain area DA of the source follower transistor are doped with the same conductivity type, and the source area SA is doped with a different conductivity type from the channel area CH and the drain area DA. Thus, charge is shifted by band-to-band tunneling at the boundary between the source area SA and the channel area CH, and a high voltage gain can be obtained while reducing noise.

According to an example embodiment, a method of manufacturing an image sensor may include providing a substrate comprising a photoelectric conversion area; and forming a source follower transistor on one side of the substrate, wherein the source follower transistor may include a source area, a channel area, and a drain area on the substrate. The source area may be doped a first conductivity type. The channel area and the drain area may be doped a second conductivity type. The second conductivity type may be different from the first conductivity type.

The first conductivity type may be P-type, and the second conductivity type may be N-type.

The forming the source follower transistor may include doping the channel at a lower doping concentration than a doping concentration of the drain area.

The source follower transistor may further include a gate electrode and a gate insulation layer. The gate electrode may overlap the channel area, and the gate insulation layer may be between the gate electrode and the channel area.

The method may further include forming a transfer transistor on the one side of the substrate; forming a floating diffusion region in the substrate; and connecting the gate electrode of the source follower transistor to the floating diffusion region.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although embodiments of the disclosure have been described in detail above, the scope of the present disclosure is not limited to the scope of the presented embodiments. On the contrary, the scope of inventive concepts is intended to cover various modifications, equivalent arrangements, and improvements within the spirit and scope of the appended claims.

### DESCRIPTION OF SYMBOLS

SF: source follower transistor; 400: first substrate
CH: channel area; DA: drain area
SA: source area; FD: floating diffusion region

What is claimed is:

1. An image sensor comprising:
a substrate comprising a photoelectric conversion area; and
a source follower transistor on one side of the substrate, wherein
the source follower transistor comprises a source area, a channel area, and a drain area on the substrate,
the source area is doped a first conductivity type,
the channel area and the drain area are doped a second conductivity type, and
the second conductivity type is different from the first conductivity type.

2. The image sensor of claim 1, wherein
the first conductivity type is P-type,
the second conductivity type is N-type,
the source area is doped with a P-type dopant, and
the channel area and the drain area are doped with an N-type dopant.

3. The image sensor of claim 1, wherein
a doping concentration of the channel area is lower than a doping concentration of the drain area.

4. The image sensor of claim 1, wherein
a doping concentration of the channel area is 1×10¹⁷ cm⁻³ to 1×10¹⁸ cm⁻³.

5. The image sensor of claim 1, wherein
a doping concentration of the source area and a doping concentration of the drain area each are 1×10¹⁹ cm⁻³ to 1×10²⁰ cm⁻³.

6. The image sensor of claim 1, wherein
a doping depth of the source area, a doping depth of the channel area, and a doping depth of the drain area each are 20 nm to 100 nm from a top surface of the substrate.

7. The image sensor of claim 1, wherein
the source follower transistor further comprises a gate electrode and a gate insulation layer,
the gate electrode overlaps the channel area, and
the gate insulation layer is between the gate electrode and the channel area.

8. The image sensor of claim 7 further comprising:
a transfer transistor on the one side of the substrate; and
a floating diffusion region connected to the transfer transistor, wherein
the gate electrode of the source follower transistor is connected to the floating diffusion region.

9. The image sensor of claim 7, wherein
a transport path of electric charges at a boundary between the source area and the channel area is closer to the gate electrode than a transport path of electric charges at a boundary between the channel area and the drain area.

10. The image sensor of claim 1, wherein
at a boundary between the source area and the channel area,
tunneling of electric charges occurs in a valence band of the source area to a conduction band of the channel area.

11. The image sensor of claim 1, wherein
a transport path of electric charge in the channel area has an L shape,
the transport path of electric charge in the channel area is positioned close to one surface of the substrate at a boundary between the source area and the channel area, and
the transport path of electric charge in the channel area is positioned far from the one surface of the substrate at a boundary between the channel area and the drain area.

12. An image sensor comprising:
a first substrate comprising a photoelectric conversion area, wherein a first surface of the first substrate is opposite a second surface of the first substrate;
a transfer transistor and a floating diffusion region on the first surface of the first substrate;
a second substrate, wherein a first surface of the second substrate is opposite and a second surface of the second substrate; and
a plurality of transistors on the first surface of the second substrate and connected to the transfer transistor,
wherein the plurality of transistors on the second substrate each comprise a reset transistor configured to initialize the floating diffusion region, a source follower transistor having a gate connected to the floating diffusion region, and a selection transistor connected to one end of the source follower transistor, and
wherein the source follower transistor comprises a source area, a channel area, and a drain area on the second substrate,
wherein the source follower transistor further includes a gate electrode overlapping the channel area,
the source area is doped a first conductivity type,
the channel area and the drain area are doped a second conductivity type, and
the second conductivity type is different from the first conductivity type.

13. The image sensor of claim 12, wherein:
the source area is doped with a P-type dopant, and
the channel area and the drain area are doped with an N-type dopant.

14. The image sensor of claim 12, wherein
a doping concentration of the channel area is lower than a doping concentration of the drain area.

15. The image sensor of claim 12, wherein
a doping concentration of the channel area is 1×10¹⁷ cm⁻³ to 1×10¹⁸ cm⁻³.

16. The image sensor of claim 12, wherein
a doping depth of the source area, a doping depth the channel area, and a doping depth of the drain area each are 20 nm to 100 nm from top surface of the first substrate.

17. The image sensor of claim 12, wherein
a transport path of electric charges at a boundary between the source area and the channel area is closer to the gate electrode than a transport path of electric charges at a boundary between the channel area and the drain area.

18. The image sensor of claim 12, wherein
at a boundary between the source area and the channel area, tunneling of electric charges occurs in a valence band of the source area to a conduction band of the channel area.

19. An image sensor comprising:
a substrate comprising a photoelectric conversion area;
a transfer transistor connected to the photoelectric conversion area;
a floating diffusion region connected to the transfer transistor;
a source follower transistor having a gate connected to the floating diffusion region;
a reset transistor configured to initialize the floating diffusion region; and
a selection transistor connected to one end of the source follower transistor, wherein
the source follower transistor comprises a source area, a channel area, and a drain area on the substrate,
the source area is doped a first conductivity type,
the channel area and the drain area are doped a second conductivity type, and
the second conductivity type is different from the first conductivity type.

20. The image sensor of claim 19, wherein
the source area is doped with a P-type dopant,
the channel area and the drain area each are doped with an N-type dopant.
